(19) United States
(12) Patent Application Publication
(10) Pub. No.: US 2022/0262801 A1
(43) Pub. Date: Aug. 18, 2022

(54) CAPACITOR DIELECTRIC FOR SHORTER CAPACITOR HEIGHT AND QUANTUM MEMORY DRAM

(71) Applicant: Applied Materials, Inc., Santa Clara, CA (US)

(72) Inventor: Russell Chin Yee TEO, Palo Alto, CA (US)

(21) Appl. No.: 17/592,397

(22) Filed: Feb. 3, 2022

Related U.S. Application Data
(60) Provisional application No. 63/150,546, filed on Feb. 17, 2021.

(51) Int. Cl. H01L 27/108; H01L 49/02; H01G 4/10; G06N 10/00

(52) U.S. Cl. CPC H01L 27/10805; H01L 28/60; G06N 10/00; H01L 27/1085; H01G 4/10

(57) ABSTRACT

Embodiments of the present disclosure generally relate to methods of forming a capacitor for DRAM. The method begins by preparing a substrate for forming the capacitor. A bottom electrode is formed on the top surface of the substrate. A dielectric layer is formed in contact with the bottom electrode. The material of the dielectric layer is one of a barium titanate, BaTiO₃ (BTO) strontium titanate, SrTiO₃ (STO), barium strontium titanate, BaSrTiO₃ (BSTO), ZrSTO, ZrBTO, or ZrBSTO. A top electrode is formed on the dielectric layer and then a cap is formed on the top electrode.

### CROSS-REFERENCE TO RELATED APPLICATIONS

This application claims benefit of U.S. Provisional Application Ser. No. 63/150,546, filed Feb. 17, 2021 (Attorney Docket No. APPM/44018686US01), of which is incorporated by reference in its entirety.

### BACKGROUND

### Field

Embodiments of the present disclosure generally relate to capacitors and memory devices having the same. More specifically, embodiments described herein relate to capacitors in memory devices and the methods of forming the capacitors in the memory devices.

### Description of the Related Art

Integrated circuits have evolved into complex devices that can include millions of transistors, capacitors, and resistors on a single chip. In the course of integrated circuit evolution, functional density of the number of interconnected devices in an area of the chip has increased while the size of the devices in that area has decreased.

As device dimensions have shrunk, maintaining switching speeds without incurring failures has become more and more challenging. Several new technologies emerged that allowed chip designers to continue shrinking gate lengths. However, capacitors, by nature, mainly rely on area and dielectric materials to be able to hold a charge. Accordingly, limits to improvements in dielectric material properties has correspondingly limited the ability of chip designers to reduce the area needed by capacitors to adequately function.

An example usage for capacitors in computing is in memory. Dynamic random-access memory (DRAM) is a-type of random access semiconductor memory that stores each bit of data in a memory cell consisting of a tiny capacitor and a transistor, both typically based on metal-oxide-semiconductor technology. DRAM is still the fastest volatile memory available on the market. Many alternative memory technologies, i.e., FeRAM, MRAM, ReRAM & PCRAM have tried to match DRAM's speed, in High-Volume-Manufacturing (HVM), without success in the last 2 decades

The capacitors in DRAM use dielectric materials such as NbO₂ (NbO), AlO₂ (AlO), ZrO₂ (ZrO), ZrNbO, ZrAlO ZrHfO, TiO₂ (TiO) and HfO₂ (HfO) to hold or store a charge corresponding a binary bit state of “1” or “0”. Conventional DRAM capacitors only allow for binary bit states of a “1” or a “0” which does not allow Quantum Computing, Deep Neural Net Computer, Quantum Memory and Quantum Displays.

The dielectric material of the capacitor is formed by conformal deposition process on top of a bottom electrode, such as TiN, after mold oxide PSG & BPSG are removed. However, these dielectric materials have a very limited charge storage capacity due to their low dielectric constant. As the DRAM BitLine (BL) pitch scales to become smaller, such as less than 40 nm for d13 node, the reduction in the BL pitch needed to increase DRAM density also requires a similar percent reduction in the capacitor (capacitor) pitch, to prevent overlay errors. As a result of the capacitor pitch reduction, the amount of the capacitor critical dimension (CD) is required to be similarly reduced. Thus, the area available for capacitor dielectric material is also reduced by a similar percent as part of DRAM unit cell reduction.

To maintain the charge capacity of the capacitor, the DRAM must have the same or greater volume of dielectric material. As the cross-sectional area of the dielectric material is reduced when the capacitor pitch is reduced, designers are required to design taller capacitor structures to accommodate the dielectric material needed to store a similar charge in the capacitor in order to maintain or increase the computational power provided by the DRAM to consumers & servers. As a result, the capacitor height may increase by a similar percent of the BL pitch reduction, for example a height above 0.9 μm, for every new DRAM node increase. In addition, due to BL pitch scaling, the amount of BitLine charge needs to be increased due to BL-BL coupling effect. As a result, the amount of capacitor charge also increases in tandem with the BitLine charge. This further increases the capacitor height well beyond 1.6 um for d13 node & below. Such a tall capacitor poses a daunting challenge for etching the final capacitor and hardmask (HM) opening in terms of maintaining the etch depth the profile control, i.e., straightness, as the height-aspect-ratio (HAR) of the capacitor may exceed 1:80.

Therefore, there is a need for an improved capacitor and method for forming the same.

### SUMMARY

Embodiments of the present disclosure generally relate to a capacitor and methods of forming the same. The method begins by preparing a substrate for forming the capacitor. A bottom electrode is formed on the top surface of the substrate. A dielectric layer is formed in contact with the bottom electrode. The material of the dielectric layer is one of a barium barium titanatetitanate, BaTiO₃ (BTO) strontiumstrontium titanatetitanate, SrTiO₃ (STO), bariumbarium strontiumstrontium titanatetitanate, BaSrTiO₃ (BSTO), ZrSTO, ZrBTO, or ZrBSTO. A top electrode is formed on the dielectric layer and then a cap is formed on the top electrode.

In another example, a method forming DRAM is provided. The method includes preparing a substrate for forming a capacitor, forming a bottom electrode of the capacitor on a top surface of the substrate, forming a dielectric layer in contact with the bottom electrode, forming a top electrode on the dielectric layer, and forming a cap on the top electrode. The material of the dielectric layer is one of a barium titanate, BaTiO₃ (BTO) strontium titanate, SrTiO₃ (STO), barium strontium titanate, BaSrTiO₃ (BSTO), ZrSTO, ZrBTO, or ZrBSTO.

In another example, a DRAM capacitor is provided. The DRAM capacitor includes a bottom electrode, a dielectric layer, a top electrode, and a cap. The bottom electrode is disposed on a top surface of a substrate. The dielectric layer is disposed in contact with the bottom electrode. The top electrode is disposed on the dielectric layer. The cap is disposed on the top electrode. The material of the dielectric layer is one of a barium titanate, BaTiO₃ (BTO) strontium titanate, SrTiO₃ (STO), barium strontium titanate, BaSrTiO₃ (BSTO), ZrSTO, ZrBTO, or ZrBSTO.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1D are schematic illustrations of various capacitors, according to embodiments.

FIG. 2 is a method of forming a capacitor on a substrate according to an embodiment.

FIG. 3 is a method for forming a dielectric layer of a capacitor.

FIG. 4 is a schematic cross-sectional view of a processing chamber suitable for forming the dielectric layer using the method of FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Disclosed herein are capacitors having a dielectric charge storage capacity increased to reduce the capacitor height and the height-aspect-ratio (HAR), along with methods for forming the same. Beneficially, the capacitors described herein allow Moore's scaling for DRAM and meet future computing needs, such as quantum computing. The capacitor may be a power-on reset (PoR) capacitor. The PoR capacitor is an electronic device incorporated into the integrated circuit that detects the power applied to the chip and generates a reset impulse that goes to the entire circuit placing it into a known state. However, it should be appreciated that the disclosure may be applied to other capacitors provided as part of an integrated circuit. Also disclosed are methods for integrating a new dielectric material that has far higher charge storage capacitance than conventional dielectric materials such as NbO, AlO, ZrO, ZrNbO, ZrAlO, ZrHfO, TiO or HfO. The new dielectric material may be one of a barium titanate, BaTiO₃ (BTO) strontium titanate, SrTiO₃ (STO), barium strontium titanate, BaSrTiO₃ (BSTO), ZrSTO, ZrBTO, or ZrBSTO dielectric. The BTO, STO, BSTO, ZrSTO, ZrBTO or ZrBSTO dielectric material can replace or alloy either NbO, AlO, ZrO, ZrNbO, ZrAlO, ZrHfO, TiO or HfO or all of NbO, AlO, ZrO, ZrNbO, ZrAlO, ZrHfO, TiO or HfO, for DRAM capacitor dielectric uses.

The new dielectric material has extremely good electro-optical properties, i.e., higher Pockel Coefficient, when deposited in-plane, in an Epi-like or a single crystal structure. The crystal structure of the new dielectric material such as barium titanate, BaTiO₃ (BTO) strontium titanate, SrTiO₃ (STO), barium strontium titanate, BaSrTiO₃ (BSTO), ZrSTO, ZrBTO, and ZrBSTO has far higher charge storage capacitance, i.e., dielectric constant, than previously used dielectric materials such as NbO, AlO, ZrO, ZrNbO, ZrAlO, ZrHfO, TiO or HfO. The planar crystallinity state of the new dielectric material enables reduced capacitor height. The better the top-down crystallinity of the dielectric material, the lower the height of the capacitor. This results in a reduced total chip height, allowing less real estate (i.e., footprint) for the device. Consequently, electronic devices such as desktops, laptops, tablets and smartphones may be slimmer, consume less power and have a longer battery life. The dielectric material, when used in DRAM capacitors, enables continuous DRAM pitch scaling and the creation of smaller DRAM unit cells, i.e., higher density DRAM per nm² area, to support future computation server and consumer product demands. Thus as compared to conventional materials utilized in the same space, the single crystal dielectric disclosed herein allows greater DRAM density, hence faster computational power and even allows for qubit quantum DRAM. Advantageously, the smaller, high capacity capacitor enables development of new quantum computing, deep neural net computers, quantum memory, and quantum display applications.

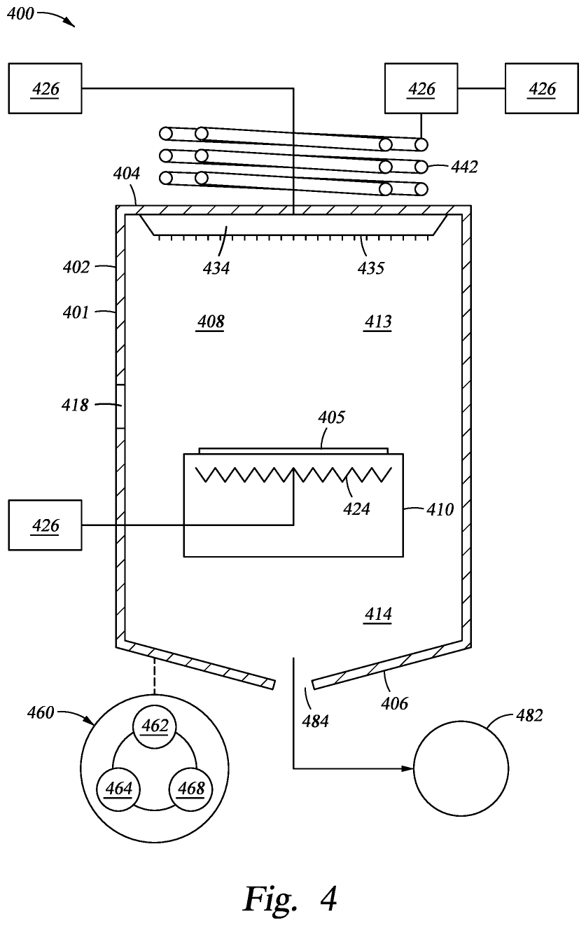

The new dielectric material can be deposited on a DRAM bottom electrode using chemical vapor deposition (CVD), physical vapor deposition (PVD), atomic layer deposition (ALD), or epitaxial layer deposition (EPI) methods. The new dielectric material reduces the capacitor height-aspect-ratio (HAR), making it easier to etch and pattern, because the features are less deep as compared to as needed with conventional dielectric materials. The processing chamber described in FIG. 4 below allows for an improvement of the crystallinity for the dielectric material from amorphous to poly to eventually to single crystal, which enables a DRAM capacitor to beneficially reap a height-aspect-ratio reduction, at every stage of the improvement.

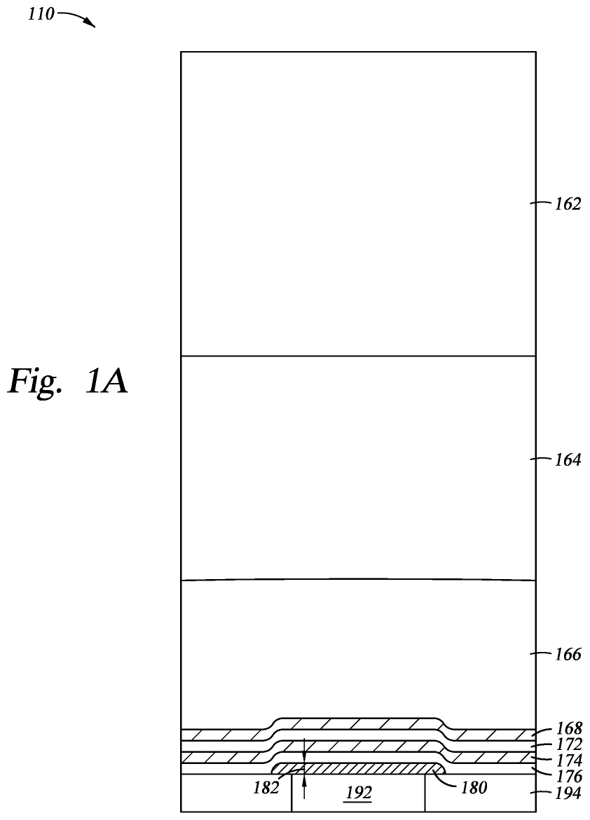

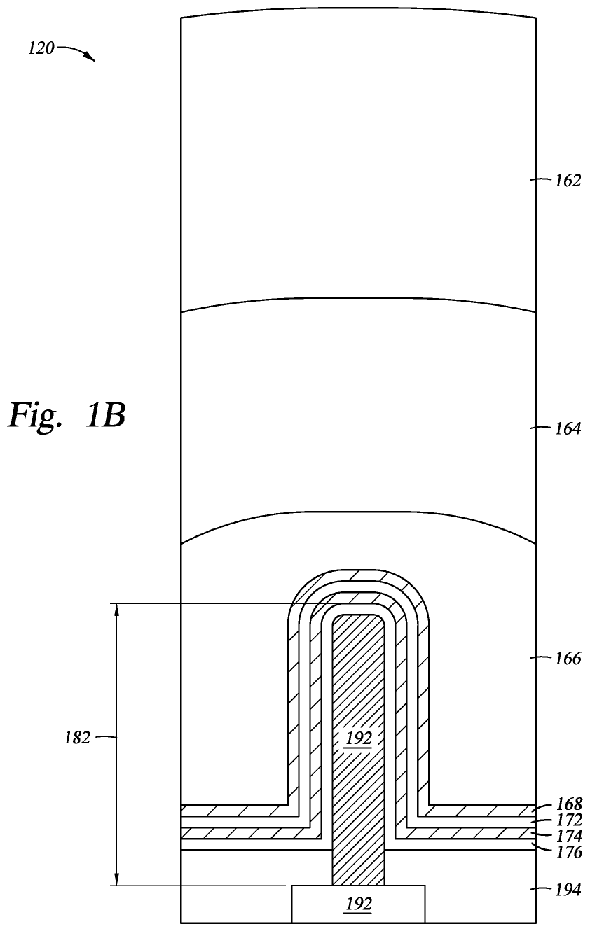

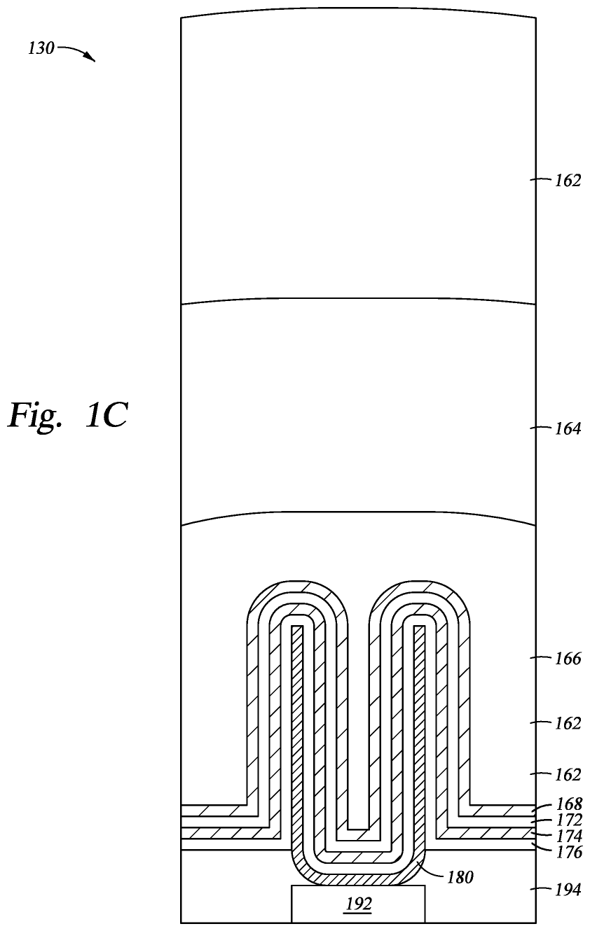

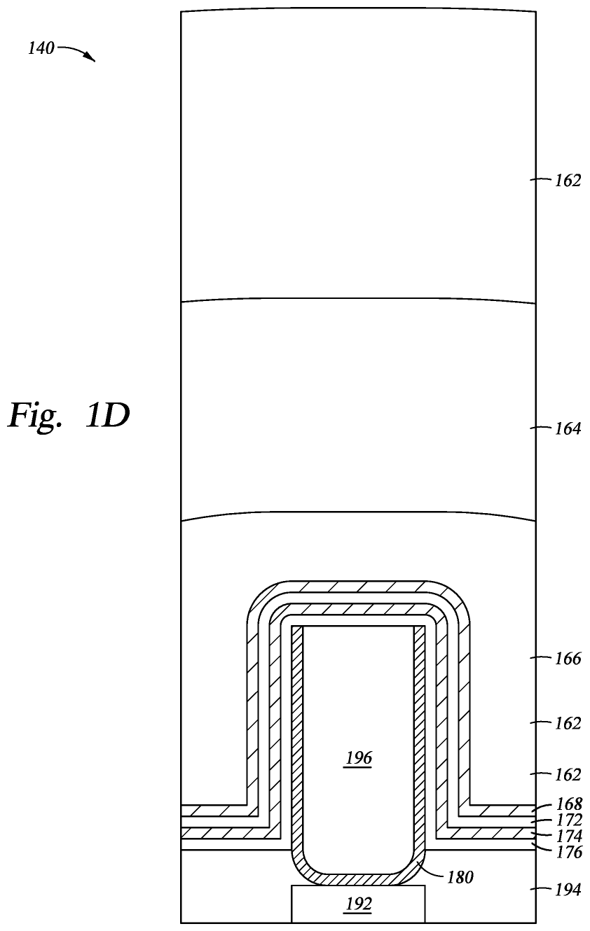

Discussed herein are four-types of capacitor integrations. To enable the four-types of capacitor integrations, a higher capacitor charge (Cₛ) is needed, hence the inventive dielectrics proposed herein. The four-types are shown in FIG. 1A-1D. Not limited to these four-types of capacitor integrations, there could be more integration for CoB and also a trench capacitor, which are not shown.

FIG. 1A illustrates a button (flat)-type integration for a capacitor-on-BitLine (CoB). The structure for a button-type capacitor 110 will be briefly described here without any discussion for the methods used in forming the button-type capacitor 110 which will be discussed later below. The button-type capacitor 110 is shown without a supporting or underlying structure such as the substrate upon which it may be formed in and the connections supplying power to and from the button-type capacitor 110.

The button-type capacitor 110 has a storage landing pad (SLP) 192 and a mechanically enhanced storage node (MESH) 194 upon which the various layers and structure of the capacitor are built. In one example, the SLP 192 may be formed from an insulating material such as Si₃N₃ and the mesh 194 may be Si₃N₄ or other suitable material. A bottom electrode 180 is formed on top of the SLP 192. The bottom electrode 180 may also extend onto the MESH 194. The bottom electrode 180 may be formed of titanium nitride (TiN), silicon nitride (SN), or other suitable material. In the button-type capacitor 110, the bottom electrode 180 is substantially flat, i. e., it does not extend vertically away from the SLP 192.

A vertical height 182 of the bottom electrode 180 from the SLP 192 is chosen to control the amount of the dielectric material utilized in the capacitor 110 for storing the capacitor charge. Thus, for the button-type capacitor 110 to be able to store a large charge, either the bottom electrode 180 has a large vertical height above the SLP 192 or the dielectric material formed on the bottom electrode 180 has a higher dielectric constant than the dielectric material currently used in conventional DRAM capacitors. In one embodiment the vertical height 182 of the bottom electrode 180 is between about 6 nm to about 450 nm. A button-type capacitor 110 having a vertical height 182 of 6 nm may require a dielectric material having a very high dielectric constant, for example a dielectric constant of above 100 or more. Dielectric materials may have various crystalline structures, for example, amorphous, polycrystalline, single cubic crystal, single tetragonal crystal, etc. The crystalline structure directly affects the dielectric constant, for example the same dielectric material having an amorphous crystalline structure may have a dielectric constant that is 1/100 of that for the same material having a single tetragonal crystal structure.

A first dielectric layer 176 is formed on the bottom electrode 180 and extends onto the MESH 194. The first dielectric layer 176 encapsulates the sides of the bottom electrode 180. The first dielectric layer 176 may be selected from the dielectric materials illustrated in Table 1 below.

TABLE 1
The dielectric constant of various oxides

| Dielectric | Dielectric constant (k) | Phase |
|---|---|---|
| SiO₂ | 3.9 | Amorphous |
| ZrO₂ | 30 | Tetragonal/cubic |
| TiO₂ | 83-100 | Rutile |
| SrTiO₃ | 300 | Cubic (single crystal) |
| BaTiO₃ | 1900 | Cubic |
| | 400-4000 (anisotropic) | Tetragonal (single crystal) |
| (Ba,Sr)TiO₃ | 6000 | Cubic |

The first dielectric layer 176 may be formed from BTO, STO, BSTO, ZrSTO, ZrBTO, ZrBSTO or other suitable material. The first dielectric layer 176 may have a thickness between about 2 nm and about 6 nm. The thickness of the first dielectric layer 176 may be smaller, or thinner, due to higher dielectric constants than conventional dielectric materials. The higher dielectric constant of the first dielectric later 176 allows the capacitor height-aspect-ratio to be kept small while reducing the risk of the top electrode shorting to an adjacent cell if there's an EPE/OVL error. If there's a need to expand the memory density or pack more computational power, the thickness of the first dielectric layer 176 can be increased to create two or more times the capacitance, which allows a greater than a 1.5 times shrinkage in the capacitor pitch with a greater than 2.25 times the memory area than conventional devices.

A second dielectric layer 174 is formed on the first dielectric layer 176. A third dielectric layer 172 is optionally formed on the second dielectric layer 174. The third dielectric layer 172 may be incorporated into the capacitor when larger capacitance or memory is desired. The third dielectric layer 172 and the second dielectric layer 174 are substantially similar to the first dielectric layer 176. For example, the third dielectric layer 172 in the second dielectric layer 174 may be formed from BTO, STO, BSTO, ZrSTO, ZrBTO, ZrBSTO or other suitable material, and each of the layers 172, 174 may have a thickness between about 2 nm and about 6 nm.

A top electrode 168 is formed on the third dielectric layer 172. Alternately, the top electrode 168 is formed on the second dielectric layer 174 when the third dielectric layer 172 is not present. The top electrode 168 may be formed of titanium nitride (TiN), silicon nitride (SN), or other suitable material. In the button-type capacitor 110, the top electrode 168 is substantially flat, i. e., conformably covers the dielectric layer 172.

A first top plate 166 is formed on the top electrode 168. The first top plate 166 may be formed from silicon-germanium (SiGe), or other suitable material. A second top plate 164 is formed on the first top plate 166. The second top plate 164 may be formed from silicon (Si), a silicon-based material, or other suitable material. A third top plate 162 is formed on the second top plate 164. The third top plate 162 may be formed from tungsten (W), or other suitable material. In one or more examples, the button capacitor 110 includes the first top place 166, the second top plate 164, and the third top plate 162. However it should be appreciated that the button capacitor 110 may have less than three top plates, for example only a first top plate 166.

The button-type capacitor 110 is substantially flat without holes, pillars, container or other structures. The button-type capacitor 110 has a conformal dielectric film over a bottom electrode. The dielectric material selected for the button-type capacitor 110 enables the compact construction while maintaining a high capacity for charge-type.

FIG. 1B illustrates a pillar-type integration for a capacitor-on-BitLine (CoB) 120. The material layers of the pillar-type capacitor 120 are substantially similar to those of the button-type capacitor 110. However, the structure for the pillar-type capacitor 120 is slightly different than the button-type capacitor 110. In the pillar-type capacitor 120, the bottom electrode 180 extends vertically away from the SLP 192. The vertical height 182 of the bottom electrode 180 from the SLP 192 is chosen to control the amount of the dielectric material for storing the capacitor charge. For example, a large vertical height 182 extends the surface area of the bottom electrode 180, which is covered by the dielectric material of the first dielectric layer 276, the second dielectric layer 274, and in some examples the third dielectric layer 272. Thus, the increase in dielectric material allows for a greater charge to be stored.

FIG. 1C illustrates a container-type integration for a capacitor-on-BitLine (CoB). The structure for the container-type capacitor 130 is slightly different than the pillar-type capacitor 120. Like in the pillar-type capacitor 120, the bottom electrode 180 extends vertically away from the SLP 192. However in the container-type capacitor 130, the bottom electrode 180 has a hollow cylinder extending from the face whereon the dielectric material is formed. Thus, the bottom electrode 180 has even a greater surface area than that disclosed in the pillar-type capacitor 120. The dielectric material not only covers an outer surface, but also the inner surface of the bottom electrode 180. Similarly, the vertical height 182 of the bottom electrode 180 from the SLP 192 is chosen to control the amount of the dielectric material for storing the capacitor charge. In this manner, a greater amount of dielectric material may be in contact with the bottom electrode 180 for storing an even greater charge while having a smaller vertical height 182. Thus, the increase of dielectric material in the container-type capacitor 130 over the pillar-type capacitor 120 allows for an even greater charge to be stored while reducing the overall height of the container-type capacitor 130.

FIG. 1D illustrates an outside-type integration for a capacitor-on-BitLine (CoB). The structure for the outside-type capacitor 140 is slightly different than the container-type capacitor 130 in that an additional amorphous silicon (a-Si) layer fills the inside the hollow cylinder of the bottom electrode 180. Thus, the bottom electrode 180 has a surface area similar to that disclosed in the pillar-type capacitor 120. The vertical height 182 of the bottom electrode 180 from the SLP 192 is chosen to control the amount of the dielectric material for storing the capacitor charge.

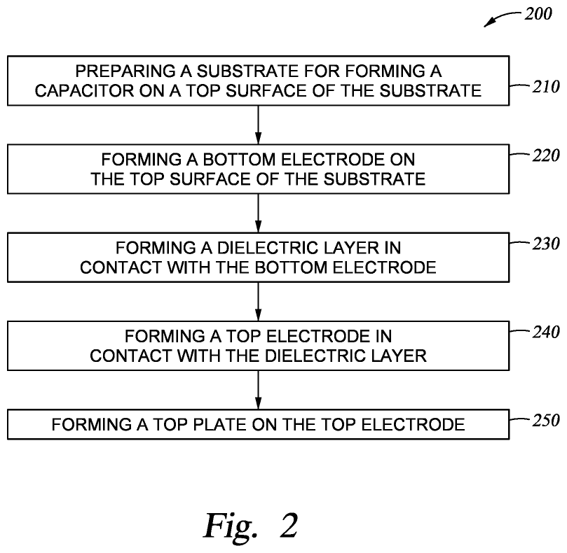

FIG. 2 is a flow diagram of a method 200 for forming a capacitor on a substrate according to an embodiment. The method 200 may be used to form capacitors used in DRAM. In particular, the capacitors in the DRAM may be any one of the button, pillar, container, or outside capacitor types shown in FIGS. 1A through 1B and discussed above.

However, it should be appreciated that other capacitor types may benefit from the method disclosed here. The method 200 begins at operation 210 by preparing a substrate for forming a capacitor on a top surface of the substrate. Preparing the substrate may involve a number of operations. For example, the substrate may be primed prior to starting with a layer of material such as silicon. A pattern operation may additionally be performed on the silicon layer. For example, a hard mask may be placed on top of the silicon layer. The hard mask may be cut, etched or otherwise have a lining cut patterned, formed or transferred onto the hard mask without edging into the silicon. A material may be filled into the hard mask. Additionally or alternately, a photoresist may be patterned and used to transfer the pattern to the substrate. In one or more operations, material is baked or removed from the substrate in preparation of further operations.

The method 200 continues at operation 220 by forming a bottom electrode on the top surface of the substrate. The bottom electrode controls the height of the capacitor and the overall amount of dielectric material used in the formation of the capacitor. For example, a container-type capacitor may have a bottom electrode height between about 450 nm and about 75 nm. In another example, the button-type capacitor may have a bottom electrode height between 4 nm and about 6 nm. It should be appreciated that the higher the height of the bottom electrode the taller the capacitor overall height is and the more complex and difficult the fabrication of the capacitor. For example, in an etch operation in which the bottom electrode is above 450 nm, maintaining a good vertical straightness is difficult and may lead to thinner areas of materials causing underperformance or defects in the capacitor.

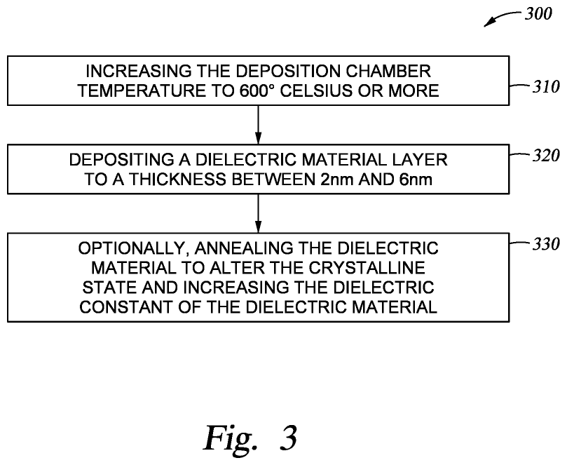

The method 200 continues at operation 230 by forming a dielectric layer in contact with the bottom electrode. Turning briefly to FIG. 3, FIG. 3 depicts a flow diagram for a method 300 for forming a dielectric layer of a capacitor. The method 300 starts at operation 310 by increasing the deposition chamber temperature to 600 degrees Celsius or more. The deposition chamber is configured with a non-aluminum body suitable for high temperature operation in a vacuum environment.

At operation 320, a dielectric material is deposited to a thickness between 2 nm and 10 nm. For example, the dielectric material may be deposited to a thickness less than 3.5 nm, such as between 2.5 nm and 3.0 nm. In one or more examples, the base dielectric layer may have a second dielectric layer and/or third dielectric layer formed on the base dielectric layer. The second and/or third dielectric layer may have a thickness independent of the thickness of the base dielectric layer.

The dielectric material thickness and height contribute to the overall amount of dielectric material in the capacitor. The dielectric material may be one or more of BTO, STO, BSTO, ZrSTO, ZrBTO or ZrBSTO, among other suitable materials. The height of the bottom electrode determines the height of the dielectric material. The height of the bottom electrode can be reduced by increasing the dielectric constant (k) of the dielectric material. The crystallinity state of the dielectric material is directly related to the dielectric constant of the material. For example in amorphous crystalline structure has a lower dielectric constant than a single tetragonal crystalline structure.

The crystallinity state of the dielectric material is determined by the temperature of the deposition of the dielectric material. For example, conventional deposition chambers deposit materials at temperatures less than 450° C., resulting in conventional dielectric materials that are is amorphous. To conventionally change the crystallinity state of the dielectric material, a conventionally deposited dielectric material requires extended heat treating, such as over a week at elevated temperatures, to change the crystallinity state of the dielectric material from an amorphous to polycrystalline state. Furthermore, the conventional deposition chambers are unsuitable for depositing BTO, STO, BSTO, ZrSTO, ZrBTO or ZrBSTO.

The capacitor charge (Cₛ) is needed to store the “1” charge for traditional power on reset (PoR) DRAM and “1/2/3/4/5” charge for qubit quantum DRAM for Write/Read operations. As devices shrink, the shrinking the real estate available for the capacitors makes it challenging for the conventional capacitors to be fabricated using conventional processing equipment. Due to BitLine pitch scaling, the amount of BitLine Charge (C_{b}) needs to increase because of the BL-BL coupling effect. If the BitLine charge (C_{b}) increases, Cₛ will increase as well. However, the area of capacitor high-k dielectric needed to store Cₛ also shrinks as the capacitor pitch always follows the shrunken BL pitch. Thus, conventional fabrication and capacitors can only increase the capacitor height as the BitLine pitch is scaled downward. But increasing capacitor height, while reducing capacitor area, means taller height-aspect-ratio (HAR) patterning, dep & etch challenges.

Beneficially, dielectric material selected from one or more of BTO, STO, BSTO, ZrSTO, ZrBTO or ZrBSTO allows greater storage of Cₛ. Furthermore, as the crystalline structure can be achieved by the deposition of the dielectric material at temperatures selected above 600° C., the BitLine pitch may be scaled downward while the height of the capacitor is also scaled downward. Table 1 above also illustrates various dielectric constants for various oxides and their crystalline structure (phase).

Table 2 below illustrates the scaling of the height and thickness or the dielectric material to form a capacitor suitable for high charge storage capacity necessary for qubit quantum DRAM.

TABLE 2

| | | capacitor | | |
|---|---|---|---|---|
| | | Dielectric | capacitor | |
| | capacitor | Total Thk | Dielectric | |
| capacitor Die Mat | Ht (μm) | (nm) | Area (nm²) | capacitor-type |
| ZrO/ZrAlO | 1.05 | 5.75 | 12075 | Container |
| ZrO/ZrAlO | 0.9 | 5 | 9000 | Container |
| ZrO/ZrAlO | 1.3 | 6 | 15600 | Container |
| ZrO/ZrAlO | 1.44 | 6.1 | 8784 | Outside |
| ZrO/ZrAlO | 1.2 | 6.1 | 7320 | Outside |
| ZrO/ZrAlO | 1.56 | | | Container |
| ZrNbO/ZrHfO/ZrAlO/ZrHfO/ZrAlO/ZrNbO | 1.4 | 6.8 | 19040 | Container |
| ZrNbO/ZrHfO/ZrAlO/ZrHfO/ZrAlO/ZrNbO | 1.27 | 7.1 | 18034 | Container |

A high temperature deposition chamber for depositing dielectric materials at temperatures of 600° C. or more, as disclosed below with respect to FIG. 4, is suitable for depositing BTO, STO, BSTO, ZrSTO, ZrBTO and ZrBSTO dielectric materials. The disclosed dielectric materials may additionally be deposited in an amorphous, polycrystalline, single cubic crystal and single tetragonal crystal state. Thus, a better top-down crystallinity of the dielectric material can be achieved and the height of the capacitor can be reduced. The reduced capacitor height allows less real estate on a chip which results in slimmer desktops, laptops, tablets and smart phones. Furthermore these devices consume less power resulting in a longer battery life. Additionally given the same real estate on the chip, a good single crystal dielectric material allows for more DRAM density. This increases the computational power and even allows for qubit quantum DRAM.

Optionally, further operations may be used to alter the crystallinity state of the dielectric material. At an optional operation 330, the dielectric material is annealed to alter the crystalline state and increase the dielectric constant of the dielectric material. Annealing is a heat treatment that alters the physical and sometimes chemical properties of the annealed dielectric material. The substrate may be moved to an annealing chamber or heat treat chamber to change the crystallinity state of the dielectric material. However, recrystallization annealing requires thermal activation at high temperatures over extended periods of time and affects the grain size for the dielectric material. Thus, depositing the dielectric material in the desired crystalline state is preferred. Stated differently, by depositing the dielectric material at temperatures exceeding 600° C., the desired crystalline state may be obtained without the need and expense of lengthy annealing processes.

Returning to FIG. 2, the method 200 continues at operation 240 by forming a top electrode in contact with the dielectric layer. The top electrode is in electrical contact with the material of dielectric material of the capacitor. The top electrode may be formed of titanium nitride (TiN), silicon nitride (SN), or other suitable material.

The method 200 continues at operation 250 by forming a top plate on the top electrode. The top plate may be formed from tungsten (W), silica (Si), a silicon-based material, silicon-germanium (SiGe), or other suitable material. A second top plate and/or a third top plate may be formed on an underlying initial or base top plate.

FIG. 4 is a schematic cross-sectional view of a processing chamber 400 suitable for forming the dielectric layer of FIG. 3. The exemplary processing chamber 400 is suitable for patterning a material layer disposed on a substrate 405 in the plasma processing chamber 400. The exemplary processing chamber 400 is suitable for performing a patterning process. One example of the plasma processing chamber 400 that may be adapted to benefit from the disclosure is a deposition chamber. For example, the plasma processing chamber 400 may be a physical vapor deposition (PVD), chemical vapor deposition (CVD), plasma-enhanced CVD (PECVD), flowable CVD (FCVD), low pressure CVD (LPCVD) atomic layer deposition (ALD), epitaxy, or other suitable processing chamber suitable for depositing the disclosed dielectric material at a high temperature of 600 degrees Celsius or more.

The plasma processing chamber 400 includes a chamber body 401 having an internal chamber volume 408 defined therein. The chamber body 401 has sidewalls 402 and a bottom 406 that are coupled to ground. The sidewalls 402 may have a liner to protect the sidewalls 402 and extend the time between maintenance cycles of the plasma processing chamber 400. The dimensions of the chamber body 401 and related components of the plasma processing chamber 400 are not limited and generally are proportionally larger than the size of the substrate 405 to be processed therein. Examples of substrate sizes include 200 mm diameter, 250 mm diameter, and 450 mm diameter, among other sizes and shapes.

The chamber body 401 may be formed from stainless steel, titanium, or other high strength material suitable for operational temperatures in excess of 600 degrees Celsius in a vacuum condition, and in some examples, up to 1000 degrees Celsius. The material of the chamber body 401 has a yield strength at temperatures exceeding 600° C. or more suitable to withstand a pressure differential of 1 ATM or more between the interior and exterior of the chamber body 401. The chamber body 401 experiences operational temperatures up to and exceeding 600° C., for example 100° C., while under vacuum conditions.

A substrate access port 418 is formed through the sidewall 402 of the chamber body 401, facilitating the transfer of the substrate 405 into and out of the plasma processing chamber 400. The access port 418 may be coupled to a transfer chamber and/or other chambers of a substrate processing system (not shown).

The chamber body 401 supports a chamber lid 404 enclosing the internal volume 408. A substrate support assembly 410 is disposed in the internal volume 408.

A pumping port 484 is formed through the bottom 406 of the chamber body 401. A pumping device 482 is coupled through the pumping port 484 to evacuate the internal volume 408 and control the pressure therein. The pumping device 482 may include one or more pumps and throttle valves.

A gas panel 432 is coupled by a gas line to the chamber body 401 to supply process gases into the internal volume 408. The gas panel 432 may include one or more process gas sources and may additionally include inert gases, non-reactive gases, and reactive gases, if desired. Examples of process gases that may be provided by the gas panel 132 include, but are not limited to, oxygen (O), barium (Br), strontium (Sr), titanium (Ti), and/or zirconium (Zr) precursor materials suitable for forming barium titanate, BaTiO₃ (BTO) strontium titanate, SrTiO₃ (STO), barium strontium titanate, BaSrTiO₃ (BSTO), ZrSTO, ZrBTO, or ZrBSTO dielectric materials.

The chamber lid 404 may include a showerhead 434. The showerhead 434 has a plurality of ports 435 for introducing the process gases from the gas panel 432 into the upper volume 413. After the process gases are introduced into the plasma processing chamber 400, the gases are energized to form plasma. An antenna 442, such as one or more inductor coils, may be provided adjacent to the plasma processing chamber 400. A power supply 446 may power the antenna 442 through a match circuit 444 to inductively couple energy, such as RF energy, to the process gas to maintain a plasma formed from the process gas in the upper volume 413 of the plasma processing chamber 400.

Alternatively, or in addition to the antenna power supply 446, process electrodes below the substrate 405 and/or above the substrate 405 may be used to capacitively couple RF power to the process gases to maintain the plasma within the internal volume 408. For example, the showerhead 434 and/or the substrate support 410 may be coupled to the power supply 446 for energizing the plasma. The operation of the power supply 446 may be controlled by a controller, such as controller 460, which also controls the operation of other components in the plasma processing chamber 400.

The controller 460 may include support circuits 468, a central processing unit (CPU) 462 and memory 464. The CPU 462 may execute instructions stored in the memory 464 to control the process sequence, regulating the gas flows from the gas panel 432 into the plasma processing chamber 400 and other process parameters. Software routines may be stored in the memory 464. Software routines are executed by the CPU 462. The execution of the software routines by the CPU 462 controls the plasma processing chamber 400 such that the processes are performed in accordance with the present disclosure. For example, the software routine may control the operation of the substrate support assembly 410.

The substrate support assembly 410 supports the substrate 405 during processing. The substrate support assembly 410 comprises an electrode 424. The electrode 424 is coupled to a bias power supply 426 and provides a bias which attracts plasma ions, formed by the process gases in the upper volume 413, to the substrate 405 positioned thereon. The bias power supply 426 may cycle on and off, or pulse, during processing of the substrate 405.

Advantageously, the BTO, STO, BSTO, ZrSTO, ZrBTO, and ZrBSTO dielectric materials reduce the capacitor height-aspect-ratio making it easier to etch and pattern. This allows for continuous DRAM pitch scaling and the creation of smaller DRAM unit cells, i.e., a higher density DRAM per nm² area, to support future computation server and consumer product demands. The dielectric material has extremely good electro-optical properties, i.e., higher Pockel coefficient, when deposited in-plane, in almost Epi-like, or single crystal structures. This allows new quantum computing, deep neural net computer, none linear switch, quantum memory and quantum display applications as the voltage threshold has a wider slope, allowing qubit energy (charge) storage in the capacitor.

While the foregoing is directed to examples of the present disclosure, other and further examples of the disclosure may be devised without departing from the basic scope thereof, and the scope thereof is determined by the claims that follow.

What is claimed is:

1. A method of forming a capacitor on a top surface of a substrate, the method comprising:
preparing a substrate for forming a capacitor;
forming a bottom electrode on the top surface of the substrate;
forming a dielectric layer in contact with the bottom electrode, wherein a material of the dielectric layer is one of a barium titanate, BaTiO₃ (BTO) strontium titanate, SrTiO₃ (STO), barium strontium titanate, BaSrTiO₃ (BSTO), ZrSTO, ZrBTO, or ZrBSTO;
forming a top electrode on the dielectric layer; and
forming a cap on the top electrode.

2. The method of claim 1 wherein forming the dielectric layer further comprises:
heating a deposition chamber to a temperature of about 600° C. or more; and
depositing the dielectric layer to a thickness between 4 nm and 6 nm.

3. The method of claim 2 wherein forming the dielectric layer further comprises:
annealing the dielectric layer to alter a crystalline state to increase a dielectric constant of the dielectric layer.

4. The method of claim 3 wherein the dielectric layer is deposited in an amorphous crystal state.

5. The method of claim 4 wherein the capacitor is a power on reset capacitor.

6. The method of claim 3 wherein the dielectric layer is deposited in a polycrystalline, single cubic crystal or single tetragonal crystal state.

7. The method of claim 6 wherein the capacitor is suitable for storing non-binary states in a qubit quantum DRAM.

8. A method of forming a DRAM, the method comprising:
preparing a substrate for forming a capacitor;
forming a bottom electrode of the capacitor on a top surface of the substrate;
forming a dielectric layer in contact with the bottom electrode, wherein a material of the dielectric layer is one of a barium titanate, BaTiO₃ (BTO) strontium titanate, SrTiO₃ (STO), barium strontium titanate, BaSrTiO₃ (BSTO), ZrSTO, ZrBTO, or ZrBSTO;
forming a top electrode on the dielectric layer; and
forming a cap on the top electrode.

9. The method of claim 8 wherein forming the dielectric layer further comprises:
heating a deposition chamber to a temperature of about 600° C. or more; and
depositing the dielectric layer to a thickness between 4 nm and 6 nm.

10. The method of claim 9 wherein forming the dielectric layer further comprises:
annealing the dielectric layer to alter a crystalline state to increase a dielectric constant of the dielectric layer.

11. The method of claim 10 wherein the dielectric layer is deposited in an amorphous crystal state.

12. The method of claim 11 wherein the capacitor is a power on reset capacitor.

13. The method of claim 12 wherein the dielectric layer is deposited in a polycrystalline, single cubic crystal or single tetragonal crystal state.

14. The method of claim 13 wherein the capacitor is suitable for storing non-binary states in a qubit quantum DRAM.

15. A DRAM capacitor, the capacitor comprising:
a bottom electrode disposed on a top surface of a substrate;
a dielectric layer disposed in contact with the bottom electrode, wherein a material of the dielectric layer is one of a barium titanate, BaTiO₃ (BTO) strontium titanate, SrTiO₃ (STO), barium strontium titanate, BaSrTiO₃ (BSTO), ZrSTO, ZrBTO, or ZrBSTO;
a top electrode disposed on the dielectric layer; and
a cap disposed on the top electrode.

16. The capacitor of claim 15 wherein the dielectric layer is in an amorphous crystal state.

17. The capacitor of claim 16 wherein the capacitor is a power on reset capacitor.

18. The capacitor of claim 15 wherein the dielectric layer is in a polycrystalline, single cubic crystal or single tetragonal crystal state.

19. The capacitor of claim 18 wherein the capacitor in the DRAM is suitable for storing non-binary states in a qubit quantum DRAM.

20. The capacitor of claim 18 wherein the dielectric layer has a thickness between 4 nm and 6 nm.
